(19) United States
(12) Patent Application Publication
(10) Pub. No.: US 2023/0418148 A1
(43) Pub. Date: Dec. 28, 2023

(54) MULTILAYER REFLECTIVE FILM-EQUIPPED SUBSTRATE, REFLECTIVE MASK BLANK, REFLECTIVE MASK, AND METHOD FOR PRODUCING SEMICONDUCTOR DEVICE

(71) Applicant: HOYA CORPORATION, Tokyo (JP)

(72) Inventors: Ikuya FUKASAWA, Tokyo (JP); Kota SUZUKI, Tokyo (JP); Masanori NAKAGAWA, Tokyo (JP)

(73) Assignee: HOYA CORPORATION, Tokyo (JP)

(21) Appl. No.: 18/039,192

(22) PCT Filed: Dec. 16, 2021
(86) PCT No.: PCT/JP2021/046485

§ 371 Date: May 26, 2023

(30) Foreign Application Priority Data
Dec. 25, 2020 (JP) 2020-217665

(51) Int. Cl. G03F 1/24

(52) U.S. Cl. CPC G03F 1/24

(57) ABSTRACT

Provided are a substrate with a multilayer reflective film comprising a protective film having high resistance to a fluorine-based etching gas used in an absorber pattern repair step without reducing a reflectance of the multilayer reflective film, a reflective mask blank, and a reflective mask.

A substrate with a multilayer reflective film 100 comprises a substrate 10, a multilayer reflective film 12 disposed on the substrate 10, and a protective film 14 disposed on the multilayer reflective film 12. The protective film 14 comprises a first metal and a second metal. Standard free energy of formation of a fluoride of the first metal is higher than standard free energy of formation of RuF₅. The second metal has an extinction coefficient of 0.03 or less at a wavelength of 13.5 nm.

### CROSS-REFERENCE TO RELATED APPLICATIONS

This application is the National Stage of International Application No. PCT/JP2021/046485, filed on Dec. 16, 2021, which claims priority to Japanese Patent Application No. 2020-217665, filed on Dec. 25, 2020, and the contents of which is incorporated by reference.

### TECHNICAL FIELD

The present disclosure relates to a substrate with a multilayer reflective film, a reflective mask blank, a reflective mask, and a method for manufacturing a semiconductor device.

### BACKGROUND ART

With a further demand for higher density and higher accuracy of a VLSI device in recent years, extreme ultraviolet (hereinafter referred to as “EUV”) lithography, which is an exposure technique using EUV light, is promising. The EUV light refers to light in a wavelength band of a soft X-ray region or a vacuum ultraviolet region, and is specifically light having a wavelength of about 0.2 to 100 nm.

A reflective mask includes a multilayer reflective film for reflecting exposure light formed on a substrate, and an absorber pattern which is a patterned absorber film formed on the multilayer reflective film for absorbing exposure light. Light incident on the reflective mask mounted on an exposure machine for performing pattern transfer on a semiconductor substrate is absorbed in a portion having an absorber pattern, and is reflected by the multilayer reflective film in a portion having no absorber pattern. A light image reflected by the multilayer reflective film is transferred onto a semiconductor substrate such as a silicon wafer through a reflective optical system.

In order to achieve high density and high accuracy of a semiconductor device using the reflective mask, a reflection region (surface of a multilayer reflective film) in the reflective mask needs to have a high reflectance with respect to EUV light that is exposure light.

As the multilayer reflective film, a multilayer film in which elements having different refractive indices are periodically layered is used. For example, as a multilayer reflective film for EUV light having a wavelength of 13 nm to 14 nm, a Mo/Si periodic layered film in which a Mo film and a Si film are alternately layered for about 40 periods is preferably used.

As a reflective mask used for EUV lithography, for example, there is a reflective mask described in Patent Document 1. Patent Document 1 describes a reflective photomask including a substrate, a reflection layer formed on the substrate and formed of a multilayer film in which two different types of films are alternately layered, a buffer layer formed on the reflection layer and formed of a ruthenium film, and an absorber pattern formed on the buffer layer in a predetermined pattern shape and made of a material capable of absorbing soft X-rays. The buffer layer described in Patent Document 1 is also generally called a protective film.

Patent Document 2 describes a substrate with a multilayer reflective film including a multilayer reflective film that reflects exposure light on a substrate. Patent Document 2 also describes that a protective film for protecting the multilayer reflective film is formed on the multilayer reflective film, and that the protective film is a protective film formed by building up a reflectance reduction suppressing layer, a blocking layer, and an etching stopper layer in this order. Patent Document 2 also describes that the etching stopper layer is made of ruthenium (Ru) or an alloy thereof, and that specific examples of the alloy of ruthenium include a ruthenium niobium (RuNb) alloy, a ruthenium zirconium (RuZr) alloy, a ruthenium rhodium (RuRh) alloy, a ruthenium cobalt (RuCo) alloy, and a ruthenium rhenium (RuRe) alloy.

Patent Documents 3 and 4 describe a substrate with a multilayer reflective film including a substrate, a multilayer reflective film, and a Ru-based protective film for protecting the multilayer reflective film, formed on the multilayer reflective film. Patent Documents 3 and 4 describe that a surface layer of the multilayer reflective film on a side opposite to the substrate is a layer containing Si.

Patent Document 3 describes that a block layer that hinders migration of Si to the Ru-based protective film is disposed between the multilayer reflective film and the Ru-based protective film. Patent Document 3 describes that examples of a constituent material of the Ru-based protective film include Ru and an alloy material thereof, and that a Ru compound containing Ru and at least one metal element selected from the group consisting of Nb, Zr, Rh, Ti, Co, and Re is suitable as the alloy of Ru.

Patent Document 4 describes that the Ru-based protective film contains a Ru compound containing Ru and Ti, and that the Ru compound contains more Ru than RuTi having a stoichiometric composition.

### PRIOR ART DOCUMENTS

### Patent Documents

Patent Document 1: JP 2002-122981 A
Patent Document 2: JP 2014-170931 A
Patent Document 3: WO 2015/012151 A
Patent Document 4: WO 2015/037564 A

### DISCLOSURE OF INVENTION

In a process of manufacturing a reflective mask, when an absorber pattern is formed, an absorber film is processed by etching via a resist pattern or an etching mask pattern. In order to process the absorber film into a designed shape, it is necessary to slightly perform over-etching on the absorber film. At the time of over-etching, a multilayer reflective film under the absorber film is also damaged by etching. In order to prevent the multilayer reflective film from being damaged by etching, a protective film is disposed between the absorber film and the multilayer reflective film. Therefore, the protective film needs to have high resistance to an etching gas used for etching the absorber film.

In addition, an absorber pattern is formed on the absorber film by etching, and then a repair step of correcting the absorber pattern so as to have a designed shape is performed. In the repair step, a black defect of the absorber pattern is irradiated with an electron beam while a fluorine-based etching gas (for example, XeF₂+H₂O) is supplied. Therefore, the protective film also needs to have high resistance to the fluorine-based etching gas in order to prevent the multilayer reflective film from being damaged by the fluorine-based etching gas used in the repair step.

Conventionally, a Ru-based material (Ru, RuNb, or the like) having high resistance to an etching gas used for etching an absorber film has been used as a material of the protective film. However, the Ru-based material has a problem that resistance to the fluorine-based etching gas used in the absorber pattern repair step is not sufficient. The protective film also needs to protect the multilayer reflective film from being damaged by the etching gas and not to reduce a reflectance of the multilayer reflective film as much as possible.

Therefore, an aspect of the present disclosure is to provide a substrate with a multilayer reflective film including a protective film having high resistance to a fluorine-based etching gas used in the absorber pattern repair step without reducing a reflectance of the multilayer reflective film, a reflective mask blank, and a reflective mask. Another aspect of the present disclosure is to provide a method for manufacturing a semiconductor device using a reflective mask including such a protective film.

In order to solve the above problems, the present disclosure has the following configurations.

(Configuration 1)

A substrate with a multilayer reflective film comprising: a substrate; a multilayer reflective film disposed on the substrate; and a protective film disposed on the multilayer reflective film, in which
the protective film comprises a first metal and a second metal,
standard free energy of formation of a fluoride of the first metal is higher than standard free energy of formation of RuF₅, and
the second metal has an extinction coefficient of 0.03 or less at a wavelength of 13.5 nm.

(Configuration 2)

The substrate with a multilayer reflective film according to configuration 1, in which the first metal is iridium (Ir).

(Configuration 3)

The substrate with a multilayer reflective film according to configuration 1, in which the first metal is rhodium (Rh).

(Configuration 4)

The substrate with a multilayer reflective film according to any one of configurations 1 to 3, in which the second metal is at least one selected from zirconium (Zr) and ruthenium (Ru).

(Configuration 5)

A reflective mask blank comprising an absorber film on the protective film of the substrate with a multilayer reflective film according to any one of configurations 1 to 4.

(Configuration 6)

The reflective mask blank according to configuration 5, in which the absorber film comprises ruthenium (Ru).

(Configuration 7)

The reflective mask blank according to configuration 5 or 6, in which
the absorber film comprises a buffer layer and an absorption layer disposed on the buffer layer,
the buffer layer comprises tantalum (Ta) or silicon (Si), and
the absorption layer comprises ruthenium (Ru).

(Configuration 8)

A reflective mask comprising an absorber pattern obtained by patterning the absorber film of the reflective mask blank according to any one of configurations 5 to 7.

(Configuration 9)

A method for manufacturing a semiconductor device, comprising performing a lithography process with an exposure apparatus using the reflective mask according to configuration 8 to form a transfer pattern on a transferred object.

The present disclosure can provide a substrate with a multilayer reflective film including a protective film having high resistance to a fluorine-based etching gas used in the absorber pattern repair step without reducing a reflectance of the multilayer reflective film, a reflective mask blank, and a reflective mask. In addition, the present disclosure can provide a method for manufacturing a semiconductor device using a reflective mask including such a protective film.

### BRIEF DESCRIPTION OF DRAWINGS

FIG. 1 is a schematic cross-sectional view illustrating an example of a substrate with a multilayer reflective film according to an embodiment.

FIG. 2 is a schematic cross-sectional view illustrating another example of the substrate with a multilayer reflective film according to the embodiment.

FIG. 3 is a schematic cross-sectional view illustrating an example of a reflective mask blank according to the embodiment.

FIG. 4 is a schematic cross-sectional view illustrating another example of the reflective mask blank according to the embodiment.

FIG. 5 is a schematic cross-sectional view illustrating another example of the reflective mask blank according to the embodiment.

FIGS. 6A to 6E are schematic views illustrating an example of a method for manufacturing a reflective mask.

FIG. 7 is a schematic diagram illustrating an example of a pattern transfer device.

### DESCRIPTION OF EMBODIMENTS

Hereinafter, an embodiment of the present disclosure will be specifically described with reference to the drawings. Note that the following embodiment is a mode for specifically describing the present disclosure and does not limit the present disclosure within the scope thereof.

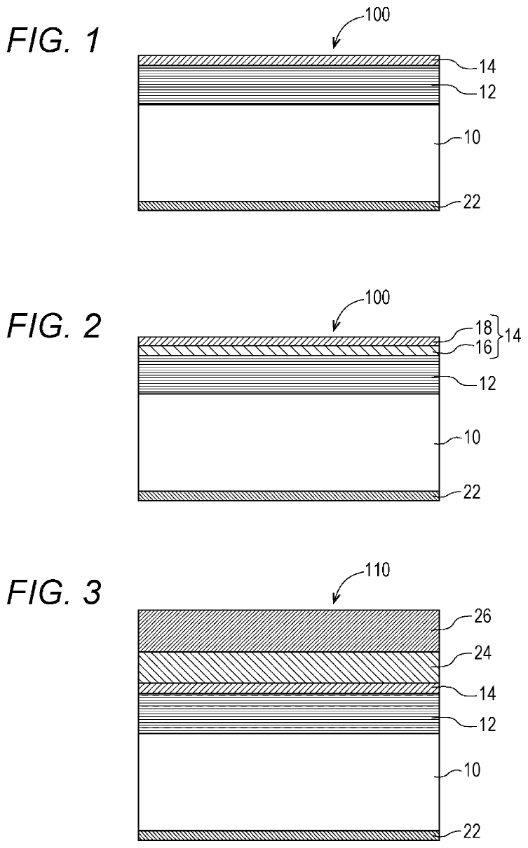

FIG. 1 is a schematic cross-sectional view illustrating an example of a substrate with a multilayer reflective film 100 according to an embodiment of the present disclosure. The substrate with a multilayer reflective film 100 illustrated in FIG. 1 includes a substrate 10, a multilayer reflective film 12 disposed on the substrate 10, and a protective film 14 disposed on the multilayer reflective film 12. A conductive back film 22 for electrostatic chuck may be formed on a back surface of the substrate 10 (surface opposite to a side where the multilayer reflective film 12 is formed).

Note that, in the present specification, “on” a substrate or a film includes not only a case of being in contact with a top surface of the substrate or the film but also a case of being not in contact with the top surface of the substrate or the film. That is, “on” a substrate or a film includes a case where a new film is formed above the substrate or the film, a case where another film is interposed between the substrate or the film and an object “on” the substrate or the film, and the like. In addition, “on” does not necessarily mean an upper side in the vertical direction. “On” merely indicates a relative positional relationship among a substrate, a film, and the like.

<Substrate>

As the substrate 10, a substrate having a low thermal expansion coefficient within a range of 0±5 ppb/° C. is preferably used in order to prevent distortion of a transfer pattern due to heat during exposure to EUV light. As a material having a low thermal expansion coefficient within this range, for example, SiO₂—TiO₂-based glass or multicomponent-based glass ceramic can be used.

A main surface of the substrate 10 on a side where a transfer pattern (absorber pattern described later) is formed is preferably processed in order to increase a flatness. By increasing the flatness of the main surface of the substrate 10, position accuracy and transfer accuracy of the pattern can be increased. For example, in a case of EUV exposure, the flatness in a region of 132 mm×132 mm of the main surface of the substrate 10 on the side where the transfer pattern is formed is preferably 0.1 m or less, more preferably 0.05 m or less, and particularly preferably 0.03 m or less. A main surface (back surface) on a side opposite to the side where the transfer pattern is formed is a surface to be fixed to an exposure apparatus by electrostatic chuck, and the flatness in a region of 142 mm×142 mm of the main surface (back surface) is preferably 0.1 m or less, more preferably 0.05 m or less, and particularly preferably 0.03 m or less. Note that, in the present specification, the flatness is a value representing warpage (deformation amount) of a surface indicated by total indicated reading (TIR). The flatness is an absolute value of a difference in height between the highest position of a substrate surface above a focal plane and the lowest position of the substrate surface below the focal plane, in which the focal plane is a plane defined by a minimum square method using the substrate surface as a reference.

In a case of EUV exposure, the main surface of the substrate 10 on the side where the transfer pattern is formed preferably has a surface roughness of 0.1 nm or less in terms of root mean square roughness (Rq). Note that the surface roughness can be measured with an atomic force microscope.

The substrate 10 preferably has a high rigidity in order to prevent deformation of a film (such as the multilayer reflective film 12) formed on the substrate 10 due to a film stress. In particular, the substrate 10 preferably has a high Young's modulus of 65 GPa or more.

<Multilayer Reflective Film>

The multilayer reflective film 12 has a structure in which a plurality of layers mainly containing elements having different refractive indices is periodically layered. Generally, the multilayer reflective film 12 is formed of a multilayer film in which a thin film (high refractive index layer) of a light element that is a high refractive index material or a compound of the light element and a thin film (low refractive index layer) of a heavy element that is a low refractive index material or a compound of the heavy element are alternately layered for about 40 to 60 periods. In order to form the multilayer reflective film 12, the high refractive index layer and the low refractive index layer may be layered in this order from the substrate 10 side for a plurality of periods. In this case, one (high refractive index layer/low refractive index layer) stack is one period.

Note that an uppermost layer of the multilayer reflective film 12, that is, a surface layer of the multilayer reflective film 12 on a side opposite to the substrate 10 is preferably formed of the high refractive index layer. When the high refractive index layer and the low refractive index layer are built up in this order from the substrate 10 side, the low refractive index layer forms the uppermost layer. However, when the low refractive index layer forms a surface of the multilayer reflective film 12, the reflectance of the surface of the multilayer reflective film 12 is reduced due to easy oxidation of the low refractive index layer. Therefore, the high refractive index layer is preferably formed on the low refractive index layer. Meanwhile, when the low refractive index layer and the high refractive index layer are built up in this order from the substrate 10 side, the high refractive index layer forms the uppermost layer. In this case, the high refractive index layer forming the uppermost layer forms a surface of the multilayer reflective film 12.

In the present embodiment, the high refractive index layer may contain Si. The high refractive index layer may contain a simple substance of Si or a Si compound. The Si compound may contain Si and at least one element selected from the group consisting of B, C, N, O, and H. By using the layer containing Si as the high refractive index layer, a multilayer reflective film having an excellent reflectance of EUV light can be obtained.

In the present embodiment, the low refractive index layer may contain at least one element selected from the group consisting of Mo, Ru, Rh, and Pt, or may contain an alloy containing at least one element selected from the group consisting of Mo, Ru, Rh, and Pt.

For example, as the multilayer reflective film 12 for EUV light having a wavelength of 13 to 14 nm, a Mo/Si multilayer film in which a Mo film and a Si film are alternately layered for about 40 to 60 periods can be preferably used. In addition, as the multilayer reflective film used in a region of EUV light, for example, a Ru/Si periodic multilayer film, a Mo/Be periodic multilayer film, a Mo compound/Si compound periodic multilayer film, a Si/Nb periodic multilayer film, a Si/Mo/Ru periodic multilayer film, a Si/Mo/Ru/Mo periodic multilayer film, a Si/Ru/Mo/Ru periodic multilayer film, or the like can be used. A material of the multilayer reflective film can be selected considering a light exposure wavelength.

The reflectance of such a multilayer reflective film 12 alone is, for example, 65% or more. An upper limit of the reflectance of the multilayer reflective film 12 is, for example, 73%. Note that the thicknesses and period of layers included in the multilayer reflective film 12 can be selected so as to satisfy Bragg's law.

The multilayer reflective film 12 can be formed by a known method. The multilayer reflective film 12 can be formed by, for example, an ion beam sputtering method.

For example, when the multilayer reflective film 12 is a Mo/Si multilayer film, a Mo film having a thickness of about 3 nm is formed on the substrate 10 by an ion beam sputtering method using a Mo target. Next, a Si film having a thickness of about 4 nm is formed using a Si target. By repeating such an operation, the multilayer reflective film 12 in which Mo/Si films are layered for 40 to 60 periods can be formed. At this time, a surface layer of the multilayer reflective film 12 on a side opposite to the substrate 10 is a layer containing Si (Si film). The Mo/Si film in one period has a thickness of 7 nm.

<Protective Film>

The protective film 14 can be formed on the multilayer reflective film 12 or in contact with a surface of the multilayer reflective film 12 in order to protect the multilayer reflective film 12 from dry etching and cleaning in a process of manufacturing a reflective mask 200 described later. The protective film 14 also has a function of protecting the multilayer reflective film 12 when a black defect in a transfer pattern (absorber pattern) is corrected using an electron beam (EB). By forming the protective film 14 on the multilayer reflective film 12, damage to the surface of the multilayer reflective film 12 can be suppressed when the reflective mask 200 is manufactured. As a result, a reflectance characteristic of the multilayer reflective film 12 with respect to EUV light is improved.

The protective film 14 can be formed by a known method. Examples of a method for forming the protective film 14 include an ion beam sputtering method, a magnetron sputtering method, a reactive sputtering method, a vapor phase growth method (CVD), and a vacuum vapor deposition method. The protective film 14 may be continuously formed by an ion beam sputtering method after the multilayer reflective film 12 is formed.

In the substrate with a multilayer reflective film 100 of the present embodiment, the protective film 14 contains a first metal and a second metal.

Standard free energy of formation of a fluoride of the first metal is higher than standard free energy of formation of RuF₅. The standard free energy (ΔG) of formation of RuF₅ is, for example, −948 kJ/mol. That is, the standard free energy of formation of the fluoride of the first metal is preferably higher than −948 kJ/mol, and more preferably higher than −700 kJ/mol.

The first metal is preferably at least one metal selected from the group consisting of iridium (Ir), palladium (Pd), gold (Au), platinum (Pt), and rhodium (Rh). The first metal is more preferably iridium (Ir). Values of standard free energy (ΔG) of formation of fluorides of these metals are, for example, as presented in Table 1 below.

TABLE 1

| First | | Standard free energy of |
|---|---|---|
| metal | Fluoride | formation (ΔG) [kJ/mol] |
| Ir | IrF₆ | −684 |
| Pd | PdF₂ | −627 |
| Au | AuF₃ | −394 |
| Pt | PtF₆ | −558 |
| Rh | RhF₃ | −551 |

An extinction coefficient (k) of the second metal at a wavelength of 13.5 nm of EUV light is 0.03 or less, and more preferably 0.02 or less. The second metal is preferably at least one metal selected from the group consisting of zirconium (Zr), ruthenium (Ru), yttrium (Y), lanthanum (La), niobium (Nb), rubidium (Rb), and titanium (Ti). The second metal is more preferably at least one selected from zirconium (Zr) and ruthenium (Ru). Extinction coefficients (k) of these metals at a wavelength of 13.5 nm are as presented in Table 2 below.

TABLE 2

| Second metal | Extinction coefficient k |
|---|---|
| Zr | 0.004 |
| Ru | 0.017 |
| Y | 0.002 |
| La | 0.005 |
| Nb | 0.005 |
| Rb | 0.001 |
| Ti | 0.017 |

The protective film 14 may contain an element other than the first metal and the second metal. For example, the protective film 14 may contain at least one element selected from the group consisting of nitrogen (N), oxygen (O), carbon (C), and boron (B).

When the protective film 14 contains nitrogen (N), the content of N is preferably 0.1 atom % or more, and more preferably 1 atom % or more. In addition, the content of N is preferably 50 atom % or less, and more preferably 25 atom % or less.

When a material of the protective film 14 contains Ir, Zr, and N, the content of N is preferably 0.1 to 50 atom %, and more preferably 1 to 25 atom %.

When the material of the protective film 14 contains Ir, Ru, and N, the content of N is preferably 0.1 to 15 atom %, and more preferably 1 to 10 atom %.

When the material of the protective film 14 contains Rh, Zr, and N, the content of N is preferably 0.1 to 50 atom %, and more preferably 1 to 25 atom %.

When the material of the protective film 14 contains Rh, Ru, and N, the content of N is preferably 0.1 to 15 atom %, and more preferably 1 to 10 atom %.

The protective film 14 can be formed by a sputtering method (co-sputtering method) using a target containing the first metal and a target containing the second metal. Alternatively, the protective film 14 can be formed by a sputtering method using an alloy containing the first metal and the second metal as a target.

Examples of a material of the protective film 14 containing the first metal and the second metal include IrZr, IrRu, RhRu, RhZr, and the like. Note that the material of the protective film 14 is not limited thereto.

The protective film 14 has etching resistance to any of a chlorine-based gas containing oxygen, a chlorine-based gas not containing oxygen, and a fluorine-based gas described later.

The protective film 14 contains the first metal, and etching resistance of the protective film 14 to a fluorine-based gas (for example, XeF₂+H₂O) is thereby improved. Standard free energy of formation of a fluoride of the first metal is higher than standard free energy of formation of RuF₅. Therefore, the protective film 14 containing the first metal has an advantageous characteristic of being less likely to react with a fluorine-based gas to form a fluoride than a protective film made of a Ru-based material used as a material of a conventional protective film.

The content of the first metal in the protective film 14 is preferably 10 atom % or more, more preferably 20 atom % or more, and still more preferably 50 atom % or more. The first metal is contained in the protective film 14 at such a ratio, and the protective film 14 is thereby less likely to react with a fluorine-based gas to form a fluoride, and therefore etching resistance of the protective film 14 to the fluorine-based gas is sufficiently enhanced.

The content of the first metal in the protective film 14 is preferably 90 atom % or less, and more preferably 80 atom % or less. When the protective film 14 contains a larger amount of the first metal than this, the extinction coefficient of the protective film 14 increases, and therefore a reflectance of the multilayer reflective film 12 with respect to EUV light may be reduced to a predetermined value or less (for example, 65% or less).

The protective film 14 contains the second metal, and the reflectance of the multilayer reflective film 12 with respect to EUV light can be thereby maintained at a predetermined value or more (for example, 65% or more).

The content of the second metal in the protective film 14 is preferably 10 atom % or more, and more preferably 20 atom % or more. The second metal is contained in the protective film 14 at such a ratio, and the reflectance of the multilayer reflective film 12 can be thereby maintained at a predetermined value or more (for example, 65% or more).

The content of the second metal in the protective film 14 is preferably 90 atom % or less, more preferably 80 atom % or less, and still more preferably less than 50 atom %. When the protective film 14 contains a larger amount of the second metal than this, there is a possibility that etching resistance to a fluorine-based gas and cleaning resistance to sulfuric acid/hydrogen peroxide mixture (SPM) is insufficient.

In view of the reflectance of the multilayer reflective film 12, the etching resistance to a fluorine-based gas, and the cleaning resistance to sulfuric acid/hydrogen peroxide mixture (SPM), a composition ratio of a specific combination of the first metal and the second metal is described below.

When the material of the protective film 14 contains Ir and Zr, a composition ratio between Ir and Zr (Ir:Zr) is preferably 9:1 to 1:9, and more preferably 4:1 to 1:4.

When the material of the protective film 14 contains Ir and Ru, a composition ratio between Ir and Ru (Ir:Ru) is preferably 9:1 to 1:9, and more preferably 4:1 to 1:4.

When the material of the protective film 14 contains Ir and Y, a composition ratio between Ir and Y (Ir:Y) is preferably 9:1 to 1:9, and more preferably 7:3 to 1:4.

When the material of the protective film 14 contains Ir and La, a composition ratio between Ir and La (Ir:La) is preferably 9:1 to 1:1, and more preferably 17:3 to 3:2.

When the material of the protective film 14 contains Ir and Nb, a composition ratio between Ir and Nb (Ir:Nb) is preferably 9:1 to 1:1, and more preferably 17:3 to 3:2.

When the material of the protective film 14 contains Ir and Rb, a composition ratio between Ir and Rb (Ir:Rb) is preferably 9:1 to 1:1, and more preferably 17:3 to 3:2.

When the material of the protective film 14 contains Ir and Ti, a composition ratio between Ir and Ti (Ir:Ti) is preferably 9:1 to 1:1, and more preferably 17:3 to 3:2.

When the material of the protective film 14 contains Pd and Zr, a composition ratio between Pd and Zr (Pd:Zr) is preferably 9:1 to 1:9, and more preferably 4:1 to 1:4.

When the material of the protective film 14 contains Pd and Ru, a composition ratio between Pd and Ru (Pd:Ru) is preferably 9:1 to 1:9, and more preferably 4:1 to 1:4.

When the material of the protective film 14 contains Pd and Y, a composition ratio between Pd and Y (Pd:Y) is preferably 9:1 to 1:9, and more preferably 7:3 to 1:4.

When the material of the protective film 14 contains Pd and La, a composition ratio between Pd and La (Pd:La) is preferably 9:1 to 1:1, and more preferably 17:3 to 3:2.

When the material of the protective film 14 contains Pd and Nb, a composition ratio between Pd and Nb (Pd:Nb) is preferably 9:1 to 1:1, and more preferably 17:3 to 3:2. When the material of the protective film 14 contains Pd and Rb, a composition ratio between Pd and Rb (Pd:Rb) is preferably 9:1 to 1:1, and more preferably 17:3 to 3:2.

When the material of the protective film 14 contains Pd and Ti, a composition ratio between Pd and Ti (Pd:Ti) is preferably 9:1 to 1:1, and more preferably 17:3 to 3:2. When the material of the protective film 14 contains Au and Zr, a composition ratio between Au and Zr (Au:Zr) is preferably 9:1 to 1:9, and more preferably 4:1 to 1:4.

When the material of the protective film 14 contains Au and Ru, a composition ratio between Au and Ru (Au:Ru) is preferably 9:1 to 1:9, and more preferably 4:1 to 1:4.

When the material of the protective film 14 contains Au and Y, a composition ratio between Au and Y (Au:Y) is preferably 9:1 to 1:9, and more preferably 7:3 to 1:4.

When the material of the protective film 14 contains Au and La, a composition ratio between Au and La (Au:La) is preferably 9:1 to 1:1, and more preferably 17:3 to 3:2.

When the material of the protective film 14 contains Au and Nb, a composition ratio between Au and Nb (Au:Nb) is preferably 9:1 to 1:1, and more preferably 17:3 to 3:2.

When the material of the protective film 14 contains Au and Rb, a composition ratio between Au and Rb (Au:Rb) is preferably 9:1 to 1:1, and more preferably 17:3 to 3:2.

When the material of the protective film 14 contains Au and Ti, a composition ratio between Au and Ti (Au:Ti) is preferably 9:1 to 1:1, and more preferably 17:3 to 3:2.

When the material of the protective film 14 contains Pt and Zr, a composition ratio between Pt and Zr (Pt:Zr) is preferably 9:1 to 1:9, and more preferably 4:1 to 1:4.

When the material of the protective film 14 contains Pt and Ru, a composition ratio between Pt and Ru (Pt:Ru) is preferably 9:1 to 1:9, and more preferably 4:1 to 1:4.

When the material of the protective film 14 contains Pt and Y, a composition ratio between Pt and Y (Pt:Y) is preferably 9:1 to 1:9, and more preferably 7:3 to 1:4.

When the material of the protective film 14 contains Pt and La, a composition ratio between Pt and La (Pt:La) is preferably 9:1 to 1:1, and more preferably 17:3 to 3:2.

When the material of the protective film 14 contains Pt and Nb, a composition ratio between Pt and Nb (Pt:Nb) is preferably 9:1 to 1:1, and more preferably 17:3 to 3:2.

When the material of the protective film 14 contains Pt and Rb, a composition ratio between Pt and Rb (Pt:Rb) is preferably 9:1 to 1:1, and more preferably 17:3 to 3:2.

When the material of the protective film 14 contains Pt and Ti, a composition ratio between Pt and Ti (Pt:Ti) is preferably 9:1 to 1:1, and more preferably 17:3 to 3:2.

When the material of the protective film 14 contains Rh and Zr, a composition ratio between Rh and Zr (Rh:Zr) is preferably 9:1 to 1:9, and more preferably 4:1 to 1:4.

When the material of the protective film 14 contains Rh and Ru, a composition ratio between Rh and Ru (Rh:Ru) is preferably 9:1 to 1:9, and more preferably 4:1 to 1:4.

When the material of the protective film 14 contains Rh and Y, a composition ratio between Rh and Y (Rh:Y) is preferably 9:1 to 1:9, and more preferably 7:3 to 1:4.

When the material of the protective film 14 contains Rh and La, a composition ratio between Rh and La (Rh:La) is preferably 9:1 to 1:1, and more preferably 17:3 to 3:2.

When the material of the protective film 14 contains Rh and Nb, a composition ratio between Rh and Nb (Rh:Nb) is preferably 9:1 to 1:1, and more preferably 17:3 to 3:2.

When the material of the protective film 14 contains Rh and Rb, a composition ratio between Rh and Rb (Rh:Rb) is preferably 9:1 to 1:1, and more preferably 17:3 to 3:2.

When the material of the protective film 14 contains Rh and Ti, a composition ratio between Rh and Ti (Rh:Ti) is preferably 9:1 to 1:1, and more preferably 17:3 to 3:2.

FIG. 2 is a schematic cross-sectional view illustrating another example of the substrate with a multilayer reflective film 100 according to the present embodiment. As illustrated in FIG. 2, the protective film 14 may include a Si material layer 16 containing silicon (Si) on a side in contact with the multilayer reflective film 12. That is, the protective film 14 may include the Si material layer 16 on the side in contact with the multilayer reflective film 12 and a protective layer 18 formed on the Si material layer 16. Similarly to the protective film 14 described above, the protective layer 18 is a layer containing the first metal and the second metal. The Si material layer 16 contains, for example, at least one material selected from silicon (Si), a silicon oxide (SiₓO_{y} (x and y are integers of 1 or more) such as SiO, SiO₂, or Si₃O₂), a silicon nitride (SiₓN_{y} (x and y are integers of 1 or more) such as SiN or Si₃N₄), and a silicon oxynitride (SiₓO_{y}N_{z} (x, y, and z are integers of 1 or more) such as SiON). The Si material layer 16 may be a Si film which is a high refractive index layer disposed as an uppermost layer of the multilayer reflective film 12 when the multilayer reflective film 12 is a Mo/Si multilayer film in which a Mo film and a Si film are layered in this order from the substrate 10 side.

The multilayer reflective film 12, the Si material layer 16, and the protective layer 18 may be formed by the same method or may be formed by different methods. For example, the multilayer reflective film 12 and the Si material layer 16 are continuously formed by an ion beam sputtering method, and then the protective layer 18 may be formed by a magnetron sputtering method. Alternatively, the multilayer reflective film 12 to the protective layer 18 may be continuously formed by an ion beam sputtering method.

A conventionally used Ru-based protective film may contain an element (Nb or the like) that reacts with a fluorine-based etching gas to form a highly volatile substance, and the highly volatile substance may cause a defect in the protective film. When a defect occurs in the protective film, the fluorine-based etching gas enters the Si material layer from the defect portion to form highly volatile SiF₄, SiF₄ expands between the protective film and the Si material layer, and a phenomenon such as destruction of the protective film may occur. According to the substrate with a multilayer reflective film 100 of the present embodiment, since the protective layer 18 contains the first metal and the second metal, and the protective layer 18 hardly reacts with the fluorine-based etching gas to form a fluoride, it is possible to prevent the fluoride from expanding between the protective layer 18 and the Si material layer 16 to destroy the protective layer 18.

FIG. 3 is a schematic cross-sectional view illustrating an example of a reflective mask blank 110 according to the present embodiment. The reflective mask blank 110 illustrated in FIG. 3 includes an absorber film 24 for absorbing EUV light on the protective film 14 of the substrate with a multilayer reflective film 100 described above. Note that the reflective mask blank 110 can further include another thin film such as a resist film 26 on the absorber film 24.

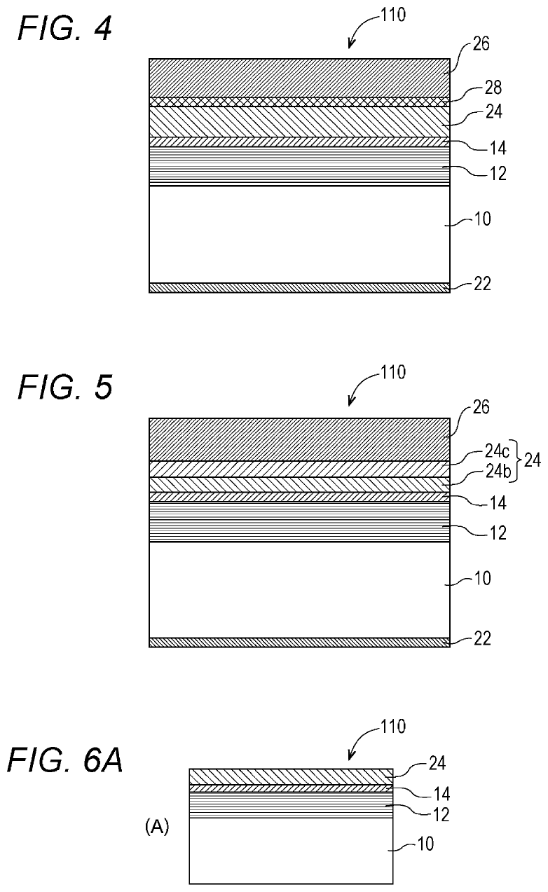

FIG. 4 is a schematic cross-sectional view illustrating another example of the reflective mask blank 110. As illustrated in FIG. 4, the reflective mask blank 110 may include an etching mask film 28 between the absorber film 24 and the resist film 26.

<Absorber Film>

The absorber film 24 of the reflective mask blank 110 of the present embodiment is formed on the protective film 14. A basic function of the absorber film 24 is to absorb EUV light. The absorber film 24 may be the absorber film 24 for the purpose of absorbing EUV light, or may be the absorber film 24 having a phase shift function in consideration of a phase difference of EUV light. The absorber film 24 having a phase shift function absorbs EUV light and reflects a part of the EUV light to shift a phase. That is, in the reflective mask 200 in which the absorber film 24 having a phase shift function is patterned, in a portion where the absorber film 24 is formed, a part of light is reflected at a level that does not adversely affect pattern transfer while EUV light is absorbed and attenuated. In addition, in a region (field portion) where the absorber film 24 is not formed, EUV light is reflected by the multilayer reflective film 12 via the protective film 14. Therefore, a desired phase difference is generated between reflected light from the absorber film 24 having a phase shift function and reflected light from the field portion. The absorber film 24 having a phase shift function is preferably formed such that a phase difference between reflected light from the absorber film 24 and reflected light from the multilayer reflective film 12 is 170 to 190 degrees. Beams of light having a reversed phase difference around 180 degrees interfere with each other at a pattern edge portion to improve an image contrast of a projected optical image. As the image contrast is improved, resolution is increased, and various exposure-related margins such as an exposure margin and a focus margin can be increased.

The absorber film 24 may be a single-layer film or a multilayer film including a plurality of films (for example, a lower absorber film and an upper absorber film). In a case of a single layer film, since the number of steps at the time of manufacturing a mask blank can be reduced, production efficiency is increased. In a case of a multilayer film, an optical constant and film thickness of an upper absorber film can be appropriately set such that the upper absorber film serves as an antireflection film at the time of mask pattern defect inspection using light. This improves inspection sensitivity at the time of mask pattern defect inspection using light. In addition, when a film containing oxygen (O), nitrogen (N), and the like that improve oxidation resistance is used as the upper absorber film, temporal stability is improved. In this manner, by forming the absorber film 24 into a multilayer film, various functions can be added to the absorber film 24. When the absorber film 24 has a phase shift function, by forming the absorber film 24 into a multilayer film, a range of adjustment on an optical surface can be increased, and therefore a desired reflectance can be easily obtained.

A material of the absorber film 24 is not particularly limited as long as the material has a function of absorbing EUV light, can be processed by etching or the like (preferably, can be etched by dry etching with a chlorine (Cl)-based gas and/or a fluorine (F)-based gas), and has a high etching selective ratio to the protective film 14. As a material having such a function, at least one metal selected from palladium (Pd), silver (Ag), platinum (Pt), gold (Au), iridium (Ir), tungsten (W), chromium (Cr), cobalt (Co), manganese (Mn), tin (Sn), tantalum (Ta), vanadium (V), nickel (Ni), hafnium (Hf), iron (Fe), copper (Cu), tellurium (Te), zinc (Zn), magnesium (Mg), germanium (Ge), aluminum (Al), rhodium (Rh), ruthenium (Ru), molybdenum (Mo), niobium (Nb), titanium (Ti), zirconium (Zr), yttrium (Y), and silicon (Si), or a compound thereof can be preferably used.

In the reflective mask blank 110 of the present embodiment, as the material of the absorber film 24, a material containing ruthenium (Ru) (Ru-based material) is preferably used. As the Ru-based material, a material containing ruthenium (Ru) and at least one element of chromium (Cr), nickel (Ni), cobalt (Co), aluminum (Al), silicon (Si), titanium (Ti), vanadium (V), germanium (Ge), niobium (Nb), molybdenum (Mo), tin (Sn), tellurium (Te), hafnium (Hf), tungsten (W), and rhenium (Re) is preferably used.

When the material of the absorber film 24 contains Ru and Cr, a composition ratio between Ru and Cr (Ru:Cr) is preferably 15:1 to 1:20.

When the material of the absorber film 24 contains Ru and Ni, a composition ratio between Ru and Ni (Ru:Ni) is preferably 20:1 to 1:4.

When the material of the absorber film 24 contains Ru and Co, a composition ratio between Ru and Co (Ru:Co) is preferably 20:1 to 1:5.

When the material of the absorber film 24 contains Ru and Al, a composition ratio between Ru and Al (Ru:Al) is preferably 20:1 to 4:5.

When the material of the absorber film 24 contains Ru and Si, a composition ratio between Ru and Si (Ru:Si) is preferably 20:1 to 1:1.

When the material of the absorber film 24 contains Ru and Ti, a composition ratio between Ru and Ti (Ru:Ti) is preferably 20:1 to 1:20.

When the material of the absorber film 24 contains Ru and V, a composition ratio between Ru and V (Ru:V) is preferably 20:1 to 1:20.

When the material of the absorber film 24 contains Ru and Ge, a composition ratio between Ru and Ge (Ru:Ge) is preferably 20:1 to 1:1.

When the material of the absorber film 24 contains Ru and Nb, a composition ratio between Ru and Nb (Ru:Nb) is preferably 20:1 to 5:1.

When the material of the absorber film 24 contains Ru and Mo, a composition ratio between Ru and Mo (Ru:Mo) is preferably 20:1 to 4:1.

When the material of the absorber film 24 contains Ru and Sn, a composition ratio between Ru and Sn (Ru:Sn) is preferably 20:1 to 3:2.

When the material of the absorber film 24 contains Ru and Te, a composition ratio between Ru and Te (Ru:Te) is preferably 20:1 to 3:1.

When the material of the absorber film 24 contains Ru and Hf, a composition ratio between Ru and Hf (Ru:Hf) is preferably 20:1 to 1:2.

When the material of the absorber film 24 contains Ru and W, a composition ratio between Ru and W (Ru:W) is preferably 20:1 to 1:20.

When the material of the absorber film 24 contains Ru and Re, a composition ratio between Ru and Re (Ru:Re) is preferably 20:1 to 1:20.

In the above description, the binary Ru-based material has been mainly described, but a ternary Ru-based material (for example, RuCrNi, RuCrCo, RuNiCo, or RuCrW) or a quaternary Ru-based material (for example, RuCrNiCo or RuCrCoW) can also be used.

The absorber film 24 may contain an element other than the above-described metals. For example, the absorber film 24 may contain at least one element selected from the group consisting of nitrogen (N), oxygen (O), carbon (C), and boron (B). Examples of a material of such an absorber film 24 include RuN, RuCrN, and RuCrO. Such an absorber film 24 can be etched with a mixed gas of a chlorine-based gas and an oxygen gas.

The absorber film 24 containing the above-described Ru-based material can be formed by a known method such as a magnetron sputtering method including a direct-current (DC) sputtering method and a radio-frequency (RF) sputtering method. For example, the absorber film 24 can be formed by a sputtering method using an alloy target containing Ru and at least one element selected from the group consisting of Cr, Ni, Co, Al, Si, Ti, V, Ge, Nb, Mo, Sn, Te, Hf, W, and Re.

In addition, the absorber film 24 can be formed by a sputtering method (co-sputtering method) using a Ru target and at least one target selected from Cr, Ni, Co, Al, Si, Ti, V, Ge, Nb, Mo, Sn, Te, Hf, W, and Re.

A Ru-based material containing Ru and at least one element of Cr, Ni, Co, V, Nb, Mo, W, and Re can be dry-etched with a chlorine-based gas containing oxygen or an oxygen gas. A Ru-based material containing Ru and at least one element of Al, Si, Ti, Ge, Sn, and Hf can be dry-etched with a chlorine-based gas not containing oxygen. As the chlorine-based gas, Cl₂, SiCl₄, CHCl₃, CCl₄, BCl₃, or the like can be used. These etching gases can each contain an inert gas such as He and/or Ar, if necessary.

In addition, a Ru-based material containing Ru and at least one element of Al, Si, Ti, Nb, Mo, Sn, Te, Hf, W, and Re can be dry-etched with a fluorine-based gas. As the fluorine-based gas, CF₄, CHF₃, C₂F₆, C₃F₆, C₄F₆, C₄F₈, CH₂F₂, C₃F₈, SF₆, or the like can be used. These etching gases may be used singly or in combination of two or more types thereof. These etching gases can each contain an inert gas such as He and/or Ar or an O₂ gas, if necessary.

According to the reflective mask blank 110 of the present embodiment, the protective film 14 contains the first metal and the second metal. The protective film 14 has sufficient resistance to an etching gas used for etching the above-described absorber film 24, and therefore can function as an etching stopper when the absorber film 24 is etched.

According to the reflective mask blank 110 of the present embodiment, the protective film 14 contains the first metal and the second metal. The protective film 14 has sufficient resistance to a fluorine-based etching gas (for example, XeF₂+H₂O) used in the absorber pattern repair step, and therefore can prevent the multilayer reflective film 12 from being damaged by the fluorine-based etching gas used in the repair step.

According to the reflective mask blank 110 of the present embodiment, the protective film 14 contains the first metal and the second metal, and therefore can maintain a reflectance of the multilayer reflective film 12 at a predetermined value or more (for example, 65% or more) while preventing the multilayer reflective film 12 from being damaged by a fluorine-based etching gas used in the repair step.

FIG. 5 is a schematic cross-sectional view illustrating another example of the reflective mask blank 110. As illustrated in FIG. 5, the absorber film 24 may include a buffer layer 24b on a side in contact with the protective film 14. That is, the absorber film 24 may include the buffer layer 24b on the side in contact with the protective film 14 and an absorption layer 24c formed on the buffer layer 24b. The absorption layer 24c is preferably made of the same material as the above-described absorber film 24, and more preferably made of a material containing Ru (Ru-based material).

Depending on selection of materials of the protective film 14 and the absorption layer 24c, there may be a problem that an etching selective ratio of the absorption layer 24c to the protective film 14 is not sufficiently high. Even in this case, it is possible to avoid the problem that the etching selective ratio of the absorption layer 24c to the protective film 14 is not high by interposing the buffer layer 24b between the protective film 14 and the absorption layer 24c.

A material of the buffer layer 24b is preferably a material containing tantalum (Ta) and one or more elements selected from oxygen (O), nitrogen (N), and boron (B). Examples of such a material include TaO, TaBO, TaN, TaBN, and the like. The buffer layer 24b containing such a material can be etched with a fluorine-based gas or a chlorine-based gas not containing oxygen.

In addition, the material of the buffer layer 24b is preferably a material containing silicon (Si), and more preferably a material containing silicon (Si) and one or more elements selected from oxygen (O) and nitrogen (N). Examples of such a material include SiO₂, SiO, SiN, SiON, SiC, SiCO, SiCN, SiCON, MoSi, MoSiO, MoSiN, MoSiON, and the like. The buffer layer 24b containing such a material can be etched with a fluorine-based gas.

The film thickness of the buffer layer 24b is preferably 0.5 nm or more, more preferably 1 nm or more, and still more preferably 2 nm or more from a viewpoint of suppressing the protective film 14 from changing optical characteristics thereof by being damaged at the time of etching the absorption layer 24c. In addition, the thickness of the buffer layer 24b is preferably 25 nm or less, more preferably 15 nm or less, still more preferably 10 nm or less, and particularly preferably less than 4 nm from a viewpoint of reducing the total thickness of the absorption layer 24c and the buffer layer 24b.

According to the reflective mask blank 110 of the present embodiment, the protective film 14 contains the first metal and the second metal. The protective film 14 has sufficient resistance to an etching gas used for etching the above-described buffer layer 24b, and therefore can function as an etching stopper when the buffer layer 24b is etched.

<Conductive Back Film>

The conductive back film 22 for electrostatic chuck is formed on a second main surface of the substrate 100 (main surface on a side opposite to the side where the multilayer reflective film 12 is formed). Sheet resistance required for the conductive back film 22 for electrostatic chuck is usually 100Ω/□ (Ω/square) or less. The conductive back film 22 can be formed, for example, by a magnetron sputtering method or an ion beam sputtering method using a target of a metal such as chromium or tantalum or an alloy thereof. A material of the conductive back film 22 is preferably a material containing chromium (Cr) or tantalum (Ta). For example, the material of the conductive back film 22 is preferably a Cr compound containing Cr and at least one selected from boron, nitrogen, oxygen, and carbon. Examples of the Cr compound include CrN, CrON, CrCN, CrCON, CrBN, CrBON, CrBCN, CrBOCN, and the like. In addition, the material of the conductive back film 22 is preferably Ta (tantalum), an alloy containing Ta, or a Ta compound containing either Ta or an alloy containing Ta and at least one of boron, nitrogen, oxygen, and carbon. Examples of the Ta compound include TaB, TaN, TaO, TaON, TaCON, TaBN, TaBO, TaBON, TaBCON, TaHf, TaHO, TaHN, TaHON, TaHON, TaHCON, TaSi, TaSiO, TaSiN, TaSiONCON, TaSi, TaSiO, TaSiN, TaSiON, TaSiCON, and the like.

The film thickness of the conductive back film 22 is not particularly limited as long as the conductive back film 22 functions as a film for electrostatic chuck, but is usually 10 nm to 200 nm. In addition, the conductive back film 22 preferably has a function of adjusting a stress on the second main surface side of the reflective mask blank 110. That is, the conductive back film 22 preferably has a function of performing adjustment such that the reflective mask blank 110 is flat by balancing a stress generated by forming a thin film on the first main surface and the stress on the second main surface.

<Etching Mask Film>

The etching mask film 28 may be formed on the absorber film 24. As a material of the etching mask film 28, a material having a high etching selective ratio of the absorber film 24 to the etching mask film 28 is preferably used. The etching selective ratio of the absorber film 24 to the etching mask film 28 is preferably 1.5 or more, and more preferably 3 or more.

When the absorber film 24 is etched with a chlorine-based gas not containing oxygen or a chlorine-based gas containing oxygen, as the material of the etching mask film 28, a material containing tantalum (Ta) and one or more elements selected from oxygen (O), nitrogen (N), and boron (B) can be used. Examples of such a material include TaO, TaBO, TaN, TaBN, and the like.

When the absorber film 24 is etched with a chlorine-based gas not containing oxygen or a chlorine-based gas containing oxygen, as the material of the etching mask film 28, a material containing silicon (Si) may be used, and a material containing silicon (Si) and one or more elements selected from oxygen (O) and nitrogen (N) is preferably used. Examples of such a material include SiO₂, SiO, SiN, SiON, SiC, SiCO, SiCN, SiCON, MoSi, MoSiO, MoSiN, MoSiON, and the like.

In addition, when the absorber film 24 is etched with a fluorine-based gas, as the material of the etching mask film 28, chromium or a chromium compound can be used. Examples of the chromium compound include a material containing Cr and at least one element selected from N, O, C, and H. The etching mask film 28 more preferably contains CrN, CrO, CrC, CrON, CrOC, CrCN, or CrOCN, and is still more preferably a CrO-based film containing chromium and oxygen (CrO film, CrON film, CrOC film, or CrOCN film).

By combination with the material of the protective film 14, damage to the protective film 14 when the etching mask film 28 is removed by dry etching can be suppressed.

The film thickness of the etching mask film 28 is preferably 3 nm or more in order to accurately form a pattern on the absorber film 24. In addition, the film thickness of the etching mask film 28 is preferably 15 nm or less in order to reduce the film thickness of the resist film 26.

<Reflective Mask>

Using the reflective mask blank 110 according to the present embodiment, the reflective mask 200 of the present embodiment can be manufactured. Hereinafter, an example of a method for manufacturing the reflective mask 200 will be described.

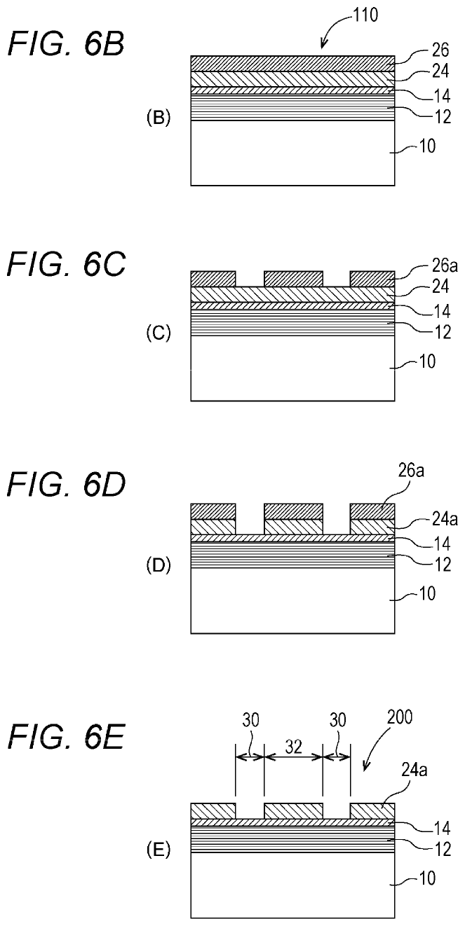

FIGS. 6A to 6E are schematic views illustrating an example of the method for manufacturing the reflective mask 200. As illustrated in FIGS. 6A to 6E, first, the reflective mask blank 110 including the substrate 10, the multilayer reflective film 12 formed on the substrate 10, the protective film 14 formed on the multilayer reflective film 12, and the absorber film 24 formed on the protective film 14 is prepared (FIG. 6A). Next, the resist film 26 is formed on the absorber film 24 (FIG. 6B). A pattern is drawn on the resist film 26 with an electron beam drawing device, and then the resulting product is subjected to a development and rinse step to form a resist pattern 26a (FIG. 6C).

The absorber film 24 is dry-etched using the resist pattern 26a as a mask. As a result, a portion not covered with the resist pattern 26a in the absorber film 24 is etched to form an absorber pattern 24a (FIG. 6D).

As an etching gas for the absorber film 24, a fluorine-based gas and/or a chlorine-based gas can be used. As the fluorine-based gas, CF₄, CHF₃, C₂F₆, C₃F₆, C₄F₆, C₄F₈, CH₂F₂, CH₃F, C₃F₈, SF₆, F₂, or the like can be used. As the chlorine-based gas, Cl₂, SiCl₄, CHCl₃, CCl₄, BCl₃, or the like can be used. In addition, a mixed gas containing a fluorine-based gas and/or a chlorine-based gas and O₂ at a predetermined ratio can be used. These etching gases can each further contain an inert gas such as He and/or Ar, if necessary.

After the absorber pattern 24a is formed, the resist pattern 26a is removed with a resist peeling liquid. After the resist pattern 26a is removed, the resulting product is subjected to a wet cleaning step using an acidic or alkaline aqueous solution to obtain the reflective mask 200 of the present embodiment (FIG. 6E).

Note that, when the reflective mask blank 110 in which the etching mask film 28 is formed on the absorber film 24 is used, a step of forming a pattern (etching mask pattern) on the etching mask film 28 using the resist pattern 26a as a mask and then forming a pattern on the absorber film 24 using the etching mask pattern as a mask is added.

The reflective mask 200 thus obtained has a structure in which the multilayer reflective film 12, the protective film 14, and the absorber pattern 24a are layered on the substrate 10.

A region 30 where the multilayer reflective film 12 (including the protective film 14) is exposed has a function of reflecting EUV light. A region 32 in which the multilayer reflective film 12 (including the protective film 14) is covered with the absorber pattern 24a has a function of absorbing EUV light. According to the reflective mask 200 of the present embodiment, since the thickness of the absorber pattern 24a having a reflectance of, for example, 2.5% or less can be made thinner than before, a finer pattern can be transferred onto a transferred object.

<Method for Manufacturing Semiconductor Device>

A transfer pattern can be formed on a semiconductor substrate by lithography using the reflective mask 200 of the present embodiment. This transfer pattern has a shape obtained by transferring a pattern of the reflective mask 200. By forming a transfer pattern on a semiconductor substrate with the reflective mask 200, a semiconductor device can be manufactured.

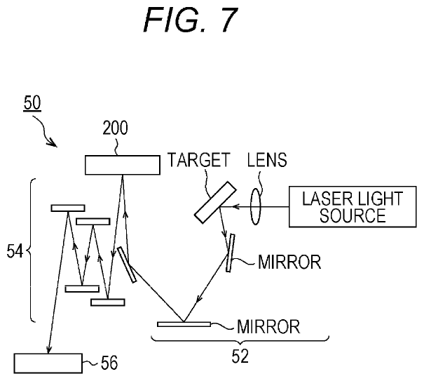

A method for transferring a pattern onto a semiconductor substrate with resist 56 using EUV light will be described with reference to FIG. 7.

FIG. 7 illustrates a pattern transfer device 50. The pattern transfer device 50 includes a laser plasma X-ray source 52, the reflective mask 200, a reduction optical system 54, and the like. As the reduction optical system 54, an X-ray reflection mirror is used.

A pattern reflected by the reflective mask 200 is usually reduced to about ¼ by the reduction optical system 54. For example, a wavelength band of 13 to 14 nm is used as a light exposure wavelength, and an optical path is set in advance so as to be in a vacuum. Under such conditions, EUV light generated by the laser plasma X-ray source 52 is allowed to enter the reflective mask 200. Light reflected by the reflective mask 200 is transferred onto the semiconductor substrate with resist 56 via the reduction optical system 54.

The light reflected by the reflective mask 200 enters the reduction optical system 54. The light that has entered the reduction optical system 54 forms a transfer pattern on a resist layer on the semiconductor substrate with resist 56. By developing the resist layer that has been exposed to light, a resist pattern can be formed on the semiconductor substrate with resist 56. By etching the semiconductor substrate 56 using this resist pattern as a mask, for example, a predetermined wiring pattern can be formed on the semiconductor substrate 56. A semiconductor device is manufactured through such a step and other necessary steps.

### Examples

Hereinafter, Examples and Comparative Example will be described with reference to the drawings.

(Substrate with a Multilayer Reflective Film 100)

First, the 6025 size (about 152 mm×152 mm×6.35 mm) substrate 10 in which the first main surface and the second main surface were polished was prepared. The substrate 10 is a substrate made of low thermal expansion glass (SiO₂—TiO₂-based glass). The main surfaces of the substrate 10 were polished through a rough polishing step, a precision polishing step, a local processing step, and a touch polishing step.

Next, the multilayer reflective film 12 was formed on the main surface (first main surface) of the substrate 10. The multilayer reflective film 12 formed on the substrate 10 was the periodic multilayer reflective film 12 including Mo and Si in order to make the multilayer reflective film 12 suitable for EUV light having a wavelength of 13.5 nm. The multilayer reflective film 12 was formed by alternately building up a Mo film and a Si film on the substrate 10 using a Mo target and a Si target by an ion beam sputtering method using krypton (Kr) as a process gas. First, a Si film was formed with a thickness of 4.2 nm, and then a Mo film was formed with a thickness of 2.8 nm. This stack was counted as one period, and the Si film and the Mo film were built up for 40 periods in a similar manner to form the multilayer reflective film 12.

Next, the Si material layer 16 was formed on the multilayer reflective film 12. The multilayer reflective film 12 and the Si material layer 16 were continuously formed by an ion beam sputtering method. The Si material layer 16 was formed with a thickness of 4.0 nm using a Si target and krypton (Kr) as a process gas.

Next, the protective layer 18 was formed on the Si material layer 16. The protective layer 18 was formed by a magnetron sputtering method (co-sputtering method) in an Ar gas atmosphere using two types of metal targets as materials of the protective layer presented in Table 3. The composition of the protective layer 18 was measured by X-ray photoelectron spectroscopy (XPS). Table 3 below presents the composition and film thickness of the protective layer 18 in each of Examples and Comparative Example.

(Evaluation of Substrate with a Multilayer Reflective Film 100)

Using the substrates with a multilayer reflective film 100 of Examples 1 to 3 and Comparative Example 1, a test for evaluating repair resistance and reflectance of the protective film 14 (protective layer 18) was performed.

First, a test for evaluating repair resistance of the protective film 14 was performed using a repair device. Specifically, irradiating a surface of the protective film 14 with an electron beam while supplying a fluorine-based etching gas (XeF₂+H₂O) to a periphery of the protective film 14 was repeated. Test conditions are as follows.

(Repair Resistance Test Conditions)
Acceleration voltage of electron beam: 1 kV
XeF₂ temperature: 0° C.
H₂O temperature: −42° C.
Electron beam irradiation time per unit pixel (1.5 nm×1.5 nm): 4.00e⁻⁸ [s]

Definition of one loop: A process of repeatedly performing scanning with an electron beam in the horizontal direction at predetermined intervals in the vertical direction to finish scanning the entire area of 500 nm×500 nm is defined as one loop

After irradiating the surface of the protective film 14 with an electron beam was repeated, the surface of the protective film 14 was photographed by SEM. Then, the number of times of electron beam irradiation (the number of loops) until damage was observed by SEM on the surface of the protective film 14 was measured. Table 3 below presents the number of times of electron beam irradiation (the number of loops) in each of Examples 1 to 3 and Comparative Example 1. In Table 3, the number of times of electron beam irradiation (the number of loops) is indicated as a ratio when the number of loops in Comparative Example 1 is 1.0.

(Reflective Mask Blank 110)

The substrates with a multilayer reflective film 100 of Examples 1 to 3 and Comparative Example 1 were manufactured separately from the substrates with a multilayer reflective film 100 used in the repair resistance test described above. The reflective mask blank 110 including the absorber film 24 was manufactured using each of the manufactured substrates with a multilayer reflective film 100. Hereinafter, a method for manufacturing the reflective mask blank 110 will be described.

The absorber film 24 (phase shift film) formed of a RuCr film was formed on the protective layer 18 of the substrate with a multilayer reflective film 100 by a DC magnetron sputtering method. The RuCr film was formed so as to have a film thickness of 45.0 nm using a RuCr target in an Ar gas atmosphere. The composition (atomic ratio) of the RuCr film was Ru:Cr=7:93.

Next, the conductive back film 22 made of CrN was formed on the second main surface (back main surface) of the substrate 10 by a magnetron sputtering method (reactive sputtering method) under the following conditions.

Conditions for forming the conductive back film 22: a Cr target, a mixed gas atmosphere of Ar and N₂ (Ar: 90 atom %, N: 10 atom %), and a film thickness of 20 nm.

As described above, the reflective mask blanks 110 of Examples 1 to 3 and Comparative Example 1 were manufactured.

(Reflective Mask 200)

Next, the reflective mask 200 was manufactured using the reflective mask blank 110 described above. The manufacture of the reflective mask 200 will be described with reference to FIGS. 6B to 6E.

First, as illustrated in FIG. 6B, the resist film 26 was formed on the absorber film 24 of the reflective mask blank 110. Next, a desired pattern such as a circuit pattern was drawn (exposed) on the resist film 26 and further developed and rinsed to form the predetermined resist pattern 26a. (FIG. 6C). Next, using the resist pattern 26a as a mask, the absorber film 24 was dry-etched using a mixed gas of a Cl₂ gas and an O₂ gas (gas flow rate ratio Cl₂:O₂=4:1) to form the absorber pattern 24a (FIG. 6D).

Thereafter, the resist pattern 26a was removed by ashing, with a resist peeling liquid, or the like. Finally, wet cleaning was performed with deionized water (DIW) to manufacture the reflective masks 200 of Examples 1 to 3 and Comparative Example 1 (FIG. 6E).

(Evaluation of Reflective Mask 200)

Using the manufactured reflective masks 200 of Examples 1 to 3 and Comparative Example 1, a test for evaluating a reflectance of the protective film 14 (protective layer 18) was performed.

A reflectance of a surface of the protective film 14 not covered with the absorber pattern 24a with respect to EUV light having a wavelength of 13.5 nm was measured. Measurement results of the reflectance in Examples 1 to 3 and Comparative Example 1 are presented in Table 3 below.

TABLE 3

| | | | Film | | Repair |
|---|---|---|---|---|---|
| | Material | | thick- | Reflec- | resistance |
| | of protec- | | ness | tance | (Number |
| | tive layer | Composition | (nm) | (%) | of loops) |
| Compara- | RuNb | Ru:Nb = 80:20 | 3.5 | 65 | 1.0 |
| tive | | | | | |
| Example 1 | | | | | |
| Example 1 | IrZr | Ir:Zr = 70:30 | 3.0 | 65 | 2.1 |
| Example 2 | IrRu | Ir:Ru = 60:40 | 3.0 | 65 | 1.5 |
| Example 3 | RhRu | Rh:Ru = 60:40 | 3.0 | 65 | 2.1 |

As can be seen from the results presented in Table 3, the number of loops of the protective film 14 of the substrate with a multilayer reflective film 100 of each of Examples 1 to 3 was larger than the number of loops of the protective film of the substrate with a multilayer reflective film of Comparative Example 1. That is, it has been found that the protective layer 18 (protective film 14) of the substrate with a multilayer reflective film 100 of each of Examples 1 to 3 has high resistance to repair by electron beam irradiation using a fluorine-based etching gas (XeF₂+H₂O).

In addition, the reflectances of the protective layers 18 (protective films 14) of the reflective masks 200 of Examples 1 to 3 were all 65% or more and maintained a predetermined value or more.

### REFERENCE SIGNS LIST

10 Substrate
12 Multilayer reflective film
14 Protective film
16 Si material layer
18 Protective layer
22 Conductive back film
24 Absorber film
24a Absorber pattern
24b Buffer layer
24c Absorption layer
26 Resist film
28 Etching mask film
100 Substrate with a multilayer reflective film
110 Reflective mask blank
200 Reflective mask

1. A substrate with a multilayer reflective film comprising: a substrate; a multilayer reflective film disposed above the substrate; and a protective film disposed above the multilayer reflective film, wherein
the protective film comprises a first metal and a second metal,
standard free energy of formation of a fluoride of the first metal is higher than standard free energy of formation of RuF₅, and
the second metal has an extinction coefficient of 0.03 or less at a wavelength of approximately 13.5 nm.

2. The substrate with a multilayer reflective film according to claim 1, wherein the first metal is iridium (Ir).

3. The substrate with a multilayer reflective film according to claim 1, wherein the first metal is rhodium (Rh).

4. The substrate with a multilayer reflective film according to claim 2, wherein the second metal is at least one selected from zirconium (Zr), ruthenium (Ru), yttrium (Y), lanthanum (La), niobium (Nb), rubidium (Rb), and titanium (Ti).

5. A reflective mask blank comprising: a substrate; a multilayer reflective film disposed above the substrate; a protective film disposed above the multilayer reflective film; and an absorber film disposed above the protective film, wherein
the protective film comprises a first metal and a second metal,
standard free energy of formation of a fluoride of the first metal is higher than standard free energy of formation of RuF₅, and
the second metal has an extinction coefficient of 0.03 or less at a wavelength of approximately 13.5 nm.

6. The reflective mask blank according to claim 5, wherein the absorber film comprises ruthenium (Ru).

7. The reflective mask blank according to claim 5, wherein
the absorber film comprises a buffer layer and an absorption layer disposed above the buffer layer,
the buffer layer comprises tantalum (Ta) or silicon (Si), and
the absorption layer comprises ruthenium (Ru).

8. A reflective mask comprising: a substrate; a multilayer reflective film disposed above the substrate; a protective film disposed above the multilayer reflective film; and an absorber film disposed above the protective film and having an absorber pattern, wherein
the protective film comprises a first metal and a second metal,
standard free energy of formation of a fluoride of the first metal is higher than standard free energy of formation of RuF₅, and
the second metal has an extinction coefficient of 0.03 or less at a wavelength of approximately 13.5 nm.

9. (canceled)

10. The reflective mask blank according to claim 5, wherein the first metal is iridium (Ir).

11. The reflective mask blank according to claim 5, wherein the first metal is rhodium (Rh).

12. The reflective mask blank according to claim 10, wherein the second metal is at least one selected from zirconium (Zr), ruthenium (Ru), yttrium (Y), lanthanum (La), niobium (Nb), rubidium (Rb), and titanium (Ti).

13. The reflective mask blank according to claim 11, wherein the second metal is at least one selected from zirconium (Zr), ruthenium (Ru), yttrium (Y), lanthanum (La), niobium (Nb), rubidium (Rb), and titanium (Ti).

14. The reflective mask according to claim 8, wherein the absorber film comprises ruthenium (Ru).

15. The reflective mask according to claim 8, wherein
the absorber film comprises a buffer layer and an absorption layer disposed above the buffer layer,
the buffer layer comprises tantalum (Ta) or silicon (Si), and
the absorption layer comprises ruthenium (Ru).

16. The reflective mask according to claim 8, wherein the first metal is iridium (Ir).

17. The reflective mask according to claim 8, wherein the first metal is rhodium (Rh).

18. The reflective mask according to claim 16, wherein the second metal is at least one selected from zirconium (Zr), ruthenium (Ru), yttrium (Y), lanthanum (La), niobium (Nb), rubidium (Rb), and titanium (Ti).

19. The reflective mask according to claim 17, wherein the second metal is at least one selected from zirconium (Zr), ruthenium (Ru), yttrium (Y), lanthanum (La), niobium (Nb), rubidium (Rb), and titanium (Ti).

20. The substrate with a multilayer reflective film according to claim 3, wherein the second metal is at least one selected from zirconium (Zr), ruthenium (Ru), yttrium (Y), lanthanum (La), niobium (Nb), rubidium (Rb), and titanium (Ti).
